(19) United States
(12) Patent Application Publication
(10) Pub. No.: US 2026/0047485 A1
(43) Pub. Date: Feb. 12, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Chuan-Lan Lin, Chiayi City (TW); Chu-Fu Lin, Kaohsiung City (TW); Min-Shiang Hsu, Kaohsiung City (TW); Chien-Ting Lin, Tainan City (TW)

(73) Assignee: UNITED MICROELECTRONICS CORP., Hsin-Chu City (TW)

(21) Appl. No.: 18/892,560

(22) Filed: Sep. 23, 2024

(30) Foreign Application Priority Data
Aug. 8, 2024 (TW) 113129760

(51) Int. Cl. H01L 25/065; H01L 21/02; H01L 21/683

(52) U.S. Cl. CPC H01L 25/0657; H01L 21/02013; H01L 21/6836; H01L 2225/06513; H01L 2225/06517

(57) ABSTRACT

A method for fabricating semiconductor device includes the steps of first providing a first wafer and a second wafer, performing a first dicing process to separate the first wafer into first dies, bonding the first dies onto the second wafer, forming a first molding layer around the first dies, forming first bumps on the first dies, performing a second dicing process to separate the second wafer for forming second dies, and then bonding the first dies onto a third wafer.

### BACKGROUND OF THE INVENTION

### 1. Field of the Invention

The invention relates to a method for fabricating semiconductor device, and more particularly, to a method of bonding multiple dies for fabricating stack structures.

### 2. Description of the Prior Art

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (PoP) devices and so on.

3DICs provide improved integration density and other advantages, such as faster speeds and higher bandwidth, because of the decreased length of interconnects between the stacked chips. However, there are quite a few challenges to be handled for the technology of 3DICs.

### SUMMARY OF THE INVENTION

According to an embodiment of the present invention, a method for fabricating semiconductor device includes the steps of first providing a first wafer and a second wafer, performing a first dicing process to separate the first wafer into first dies, bonding the first dies onto the second wafer, forming a first molding layer around the first dies, forming first bumps on the first dies, performing a second dicing process to separate the second wafer for forming second dies, and then bonding the first dies onto a third wafer.

According to another aspect of the present invention, a semiconductor device includes a first die bonded to a substrate, a second die on the first die, a third die on the second die, a fourth die on the third die, and a molding layer around the first die, the second die, and the third die.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-11 illustrate a method for fabricating a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

Referring to FIGS. 1-11, FIGS. 1-11 illustrate a method for fabricating a semiconductor device according to an embodiment of the present invention. As shown in FIG. 1, a first wafer such as wafer 12 and a second wafer such as wafer 14 both made of semiconductor material are provided. Preferably, each of the wafers 12, 14 include a substrate 16 made of semiconductor materials as the substrate 16 could also be made of semiconductor substrate material including but not limited to for example silicon substrate, epitaxial silicon substrate, silicon carbide substrate or even a silicon-on-insulator (SOI) substrate, which are all within the scope of the present invention. In this embodiment, each of the wafers 12, 14 could be used for fabricating elements including MV devices, HV devices, pixel circuits, LV devices for LV driving circuits, and/or graphics process unit (GPU).

Next, a front end of line (FEOL) and a back end of line (BEOL) fabrication processes could be conducted on the wafers 12, 14 respectively while the wafer 12 is adhered onto the carrier 18. In this embodiment, the FEOL process could include the process of forming metal-oxide semiconductor (MOS) transistors, oxide semiconductor field effect transistors (OS FETs), fin field effect transistor (FinFETs), or other active devices and/or passive devices. BEOL process on the other hand could include forming metal interconnect structures such as metal inter-metal dielectric (IMD) layers and metal interconnections 24 on the aforementioned active devices and/or passive devices.

If a MOS transistor were to be fabricated, the FEOL process could include the steps of forming a gate structure on the substrate 16, forming a spacer (not shown) adjacent to sidewalls of the gate structure and a source/drain region in the substrate 16 adjacent to two sides of the spacer, in which the gate structure could include polysilicon or metal, the spacer could include dielectric material such as silicon oxide or silicon nitride, and the source/drain region could include p-type dopants or n-type dopants depending on the conductive type of the transistor being fabricated.

Next, an interlayer dielectric (ILD) layer could be formed on the substrate 16 to cover the MOS transistor or other active devices, and then a contact plug formation and metal interconnect process from BEOL process could be conducted to form a plurality of contact plugs in the ILD layer for connecting the source/drain region and the gate structure, an inter-metal dielectric (IMD) layer 18 disposed on the ILD layer, and metal interconnections 20 in the IMD layer for connecting the contact plugs, in which the topmost metal interconnection 20 on front side of the wafers 12, 14 could be used as connecting junctions such as direct bond interconnects (DBIs) as the two wafers could be bonded through DBIs in the later process. In this embodiment, the ILD layer and the IMD layer 18 could include oxides including but not limited to for example tetraethyl orthosilicate (TEOS) and the contact plugs and the metal interconnections 20 or DBIs could include Al, Cr, Cu, Ta, Mo, W, or combination thereof.

It should be noted that through-silicon vias (TSVs) 22 are formed in the substrate 16 of the wafer 12 to connect to the active devices and/or passive devices on the substrate 16 while no TSVs are formed in the substrate 16 of the wafer 14.

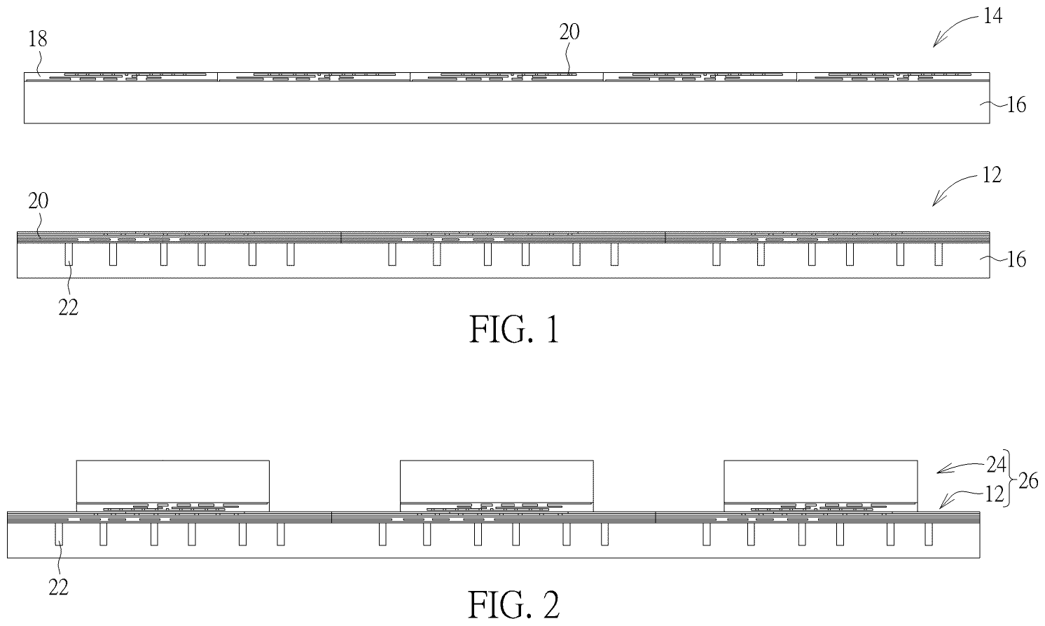

Next, as shown in FIG. 2, an optional grinding process could be conducted on backside of the wafer 14 to remove part of the substrate 16 by lowering its overall thickness, a dicing process is conducted to separate the wafer 14 into a plurality of first dies such as dies 24, and then bonding the dies 24 onto the wafer 12. According to an embodiment of the present invention, a hybrid bonding process could be conducted to bond the dies 24 onto the wafer 14. Preferably, the bonding process could be accomplished by first reversing the dies 24 so that the front side of the dies 24 or the exposed surface of the metal interconnections 20 or DBIs is facing toward the front side of the wafer 12 or the exposed surface of the metal interconnections 20, and then performing a thermal treatment process to directly bond the dies 24 and the wafer 12 by directly contacting the metal interconnections 20 on the dies 24 and the wafer 12 thereby forming a first stack structure 26.

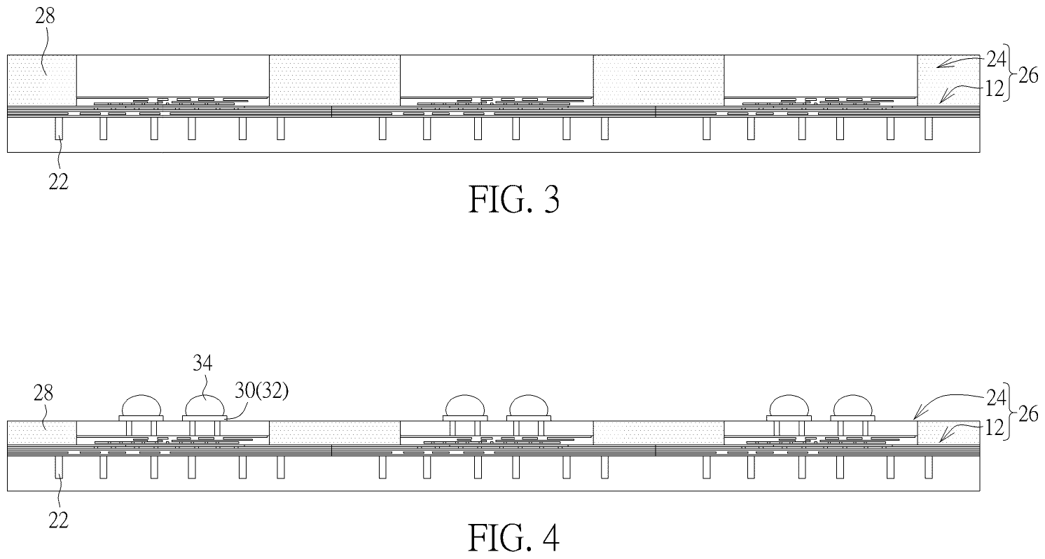

Next, as shown in FIG. 3, a molding layer 28 is formed on the wafer 12 to surround the dies 24, and then a grinding process is conducted to remove part of the molding layer 28 so that the top surfaces of the molding layer 28 and the dies 24 are coplanar. Preferably, the height of the molding layer 28 at this stage is between 700-800 microns or most preferably 750 microns. According to an embodiment of the present invention, the molding layer 28 could include organic or inorganic material such as oxides of fluorinated silicate glass (FSG). Moreover, the molding layer 28 could also include polymers such as thermosetting polymers, thermoplastic polymers, or combination thereof. Furthermore, the molding layer 28 could include plastic materials, epoxy resin, polyimide, polyethylene terephthalate (PET), polyvinyl chloride, (PVC), polymethyl methacrylate (PMMA), polymers including filler, or combination thereof.

Next, as shown in FIG. 4, another grinding process is conducted to remove part of the dies 24 and part of the molding layer 28 so that the heights of the dies 24 and molding layer 28 are reduced to approximately 3-5 microns, a bonding pad fabrication process is conducted to form redistribution layers (RDLs) 30 and bonding pads 32 on one side such as top surface of the dies 24 and stack structure 26, and then bumps 34 such as micro bumps or solder balls are formed on the bonding pads 32. In this embodiment, the RDL 30, the bonding pads 32, and the bumps 34 could include aluminum (Al), copper (Cu), silver (Ag), gold (Au), nickel (Ni), tungsten (W), or alloy thereof.

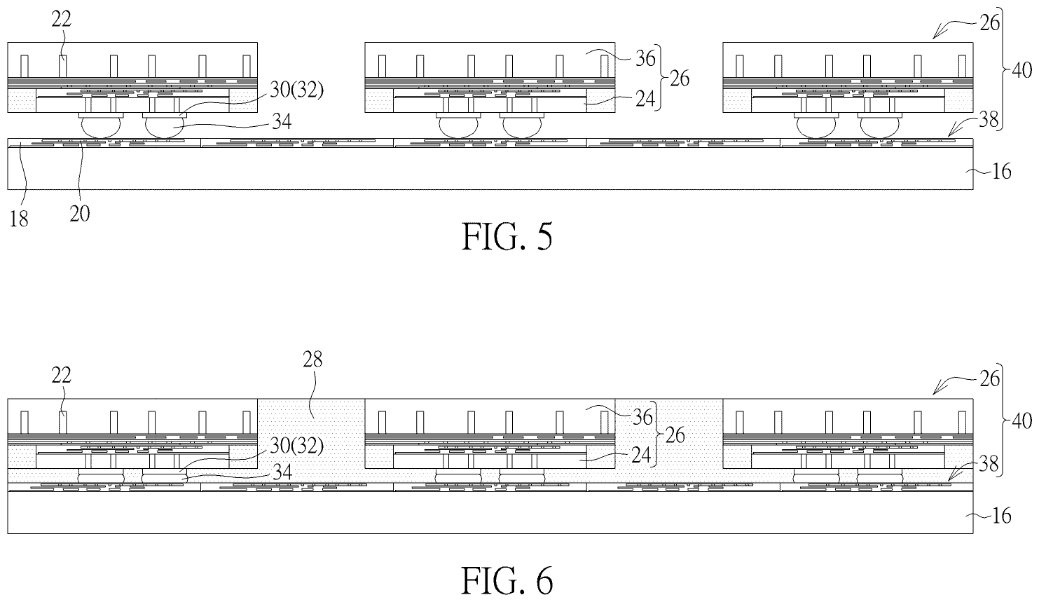

Next, as shown in FIG. 5, a dicing process is conducted to divide the stack structure 26 or wafer 12 and the molding layer 28 atop into a plurality of second dies such as dies 36, and then bond the diced dies 36 to a third wafer such as wafer 38.

Similar to the wafer 14 shown in FIG. 1, the wafer 38 also includes a substrate 16 made of semiconductor material and a front end of line (FEOL) and a back end of line (BEOL) fabrication processes could be conducted on the substrate 16 of the wafer 38. Preferably, the FEOL process could include the process of forming metal-oxide semiconductor (MOS) transistors, oxide semiconductor field effect transistors (OS FETs), fin field effect transistor (FinFETs), or other active devices and/or passive devices, and BEOL process on the other hand could include forming metal interconnect structures such as metal inter-metal dielectric (IMD) layers 18 and metal interconnections 20 on the aforementioned active devices and/or passive devices.

According to an embodiment of the present invention, after the wafer 12 is diced through dicing process, the dies 36 or stack structures 26 obtained could be reversed so that the front side of the dies 24 with the bumps 34 is facing toward front side or the side exposing metal interconnections 20 of the wafer 38, and then a thermal treatment process is conducted to directly bond the stack structures 26 and the wafer 38 for forming a stack structure 40.

Next, as shown in FIG. 6, a molding layer 28 is formed around the dies 24 and the dies 36, and then a grinding process is conducted to remove part of the molding layer 28 so that the top surface of the molding layer 28 is even with the top surface of the dies 36.

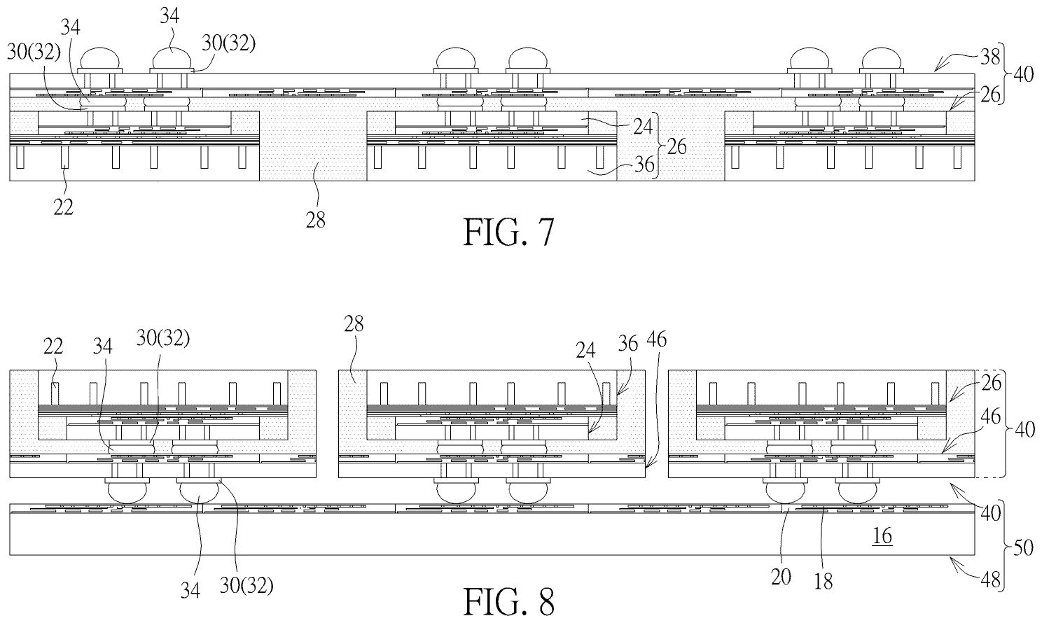

Next, as shown in FIG. 7, the stack structure 40 is reversed, and then a grinding process is conducted to remove part of the substrate 16 of the wafer 38 for reducing its overall thickness. Similar to FIG. 4, a bonding pad formation process is then conducted to form redistribution layers (RDLs) 30 and bonding pads 32 on one side such as top surface of the wafer 38 or the stack structure 40, and then bumps 34 such as micro bumps or solder balls are formed on the bonding pads 32. Preferably, the RDL 30, the bonding pads 32, and the bumps 34 could include aluminum (Al), copper (Cu), silver (Ag), gold (Au), nickel (Ni), tungsten (W), or alloy thereof.

Next, as shown in FIG. 8, a dicing process is conducted to separate the stack structure 40 or wafer 38 and the molding layer 28 underneath into a plurality of third dies such as dies 46, and then the diced dies 46 are bonded onto a fourth wafer such as wafer 48. It should be noted that after the dicing process is completed, the width of each die 46 formed at this stage is greater than the width of each die 36 and the width of each die 36 is also greater than the width of each die 24.

Similar to the wafer 38 shown in FIG. 5, the wafer 48 also includes a substrate 16 made of semiconductor material and a front end of line (FEOL) and a back end of line (BEOL) fabrication processes could be conducted on the substrate 16 of the wafer 48. Preferably, the FEOL process could include the process of forming metal-oxide semiconductor (MOS) transistors, oxide semiconductor field effect transistors (OS FETs), fin field effect transistor (FinFETs), or other active devices and/or passive devices, and BEOL process on the other hand could include forming metal interconnect structures such as metal inter-metal dielectric (IMD) layers 18 and metal interconnections 20 on the aforementioned active devices and/or passive devices.

According to an embodiment of the present invention, after the wafer 38 is diced through dicing process, the dies 46 or stack structures 40 could be reversed so that the front side of the dies 46 having bumps 34 is facing toward front side of the wafer 48, and then a thermal treatment process is conducted to directly bond the stack structures 40 and the wafer 48 for forming a stack structure 50.

Next, as shown in FIG. 9, a molding layer 28 is formed around the dies 24, the dies 36, and the dies 46, and then a grinding process is conducted to remove part of the molding layer 28 so that the top surface of the molding layer 28 is even with the top surface of the dies 36. Next, the stack structure 50 could be reversed, and then a grinding process is conducted to remove part of the substrate 16 of the wafer 48 for reducing its overall thickness.

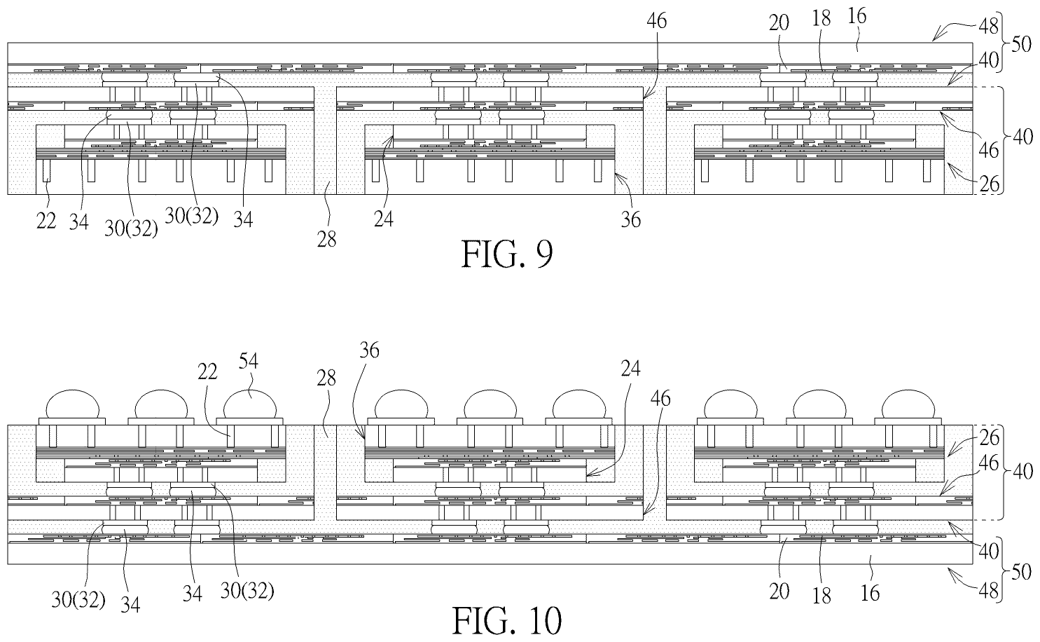

Next, as shown in FIG. 10, the stack structure 50 is reversed, a selective grinding process is conducted to remove part of the dies 36 and part of the molding layer 28 for exposing the TSVs 22 embedded in the dies 36, and then solder balls 54 are formed on the dies 36 to connect to the TSVs 22.

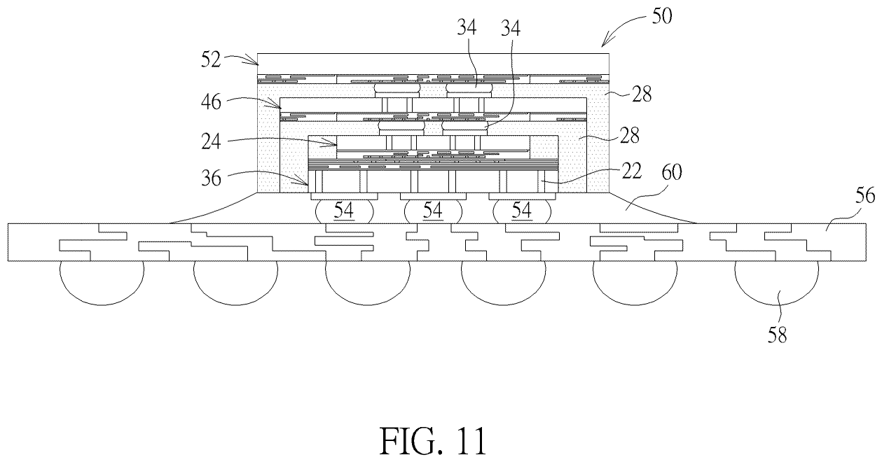

Next, as shown in FIG. 11, the stack structure 50 is reversed once more, and then a dicing process is conducted to divide the wafer 48 and the molding layer 28 into a plurality of fourth dies such as dies 52. Next, the separated stack structure 50 is adhered onto one side such as top side of another substrate 56 through an underfill layer 60, and then a plurality of solder balls 58 are formed under the substrate 56. This completes the fabrication of a semiconductor device according to an embodiment of the present invention. It should be noted that even though the above embodiment forms the TSVs 22 in the substrate 16 of the wafer 12 in FIG. 1, alternatively, according to other embodiment of the present invention, it would also be desirable to move the timing of forming the TSVs 22 after stacking multiple dies and before the dicing process is performed. For instance, it would be desirable to first provide wafers 12, 14 having substrates 16 with no TSVs embedded therein in FIG. 1, stack multiple dies according to fabrication processes conducted in FIGS. 2-10, reverse the stack structure 50 in FIG. 10, and then form TSVs 22 in the dies 36 and solder balls 54 on the dies 36 to connect to the TSVs 22, which is also within the scope of the present invention.

Referring again to FIG. 11, FIG. 11 further illustrates a structural view of a semiconductor device according to an embodiment of the present invention. As shown in FIG. 11, the semiconductor device includes four sets of dies including a die 36 bonded to a substrate 56, a die 24 disposed on the die 36, a die 46 disposed on the die 24, a die 52 disposed on the die 46, and a molding layer 28 around the dies 36, 24, 46, 52. Semiconductor device also includes bumps 34 disposed between the dies 24 and 46, bumps disposed between the dies 46 and 52, and solder balls 54 disposed between the lowest level die 36 and the substrate 56. In this embodiment, the dies preferably have different widths. For instance, the width of the lowest level die 36 is greater than the width of the die 24 atop, the width of the die 24 is less the width of the die 46 atop, and the width of the die 46 is less than the width of the die 52 atop. In other words, the second level die 24 from bottom to top or the die 24 obtained from dicing the wafer 14 in the beginning has smallest width, the bottom level die 36 or the die 36 obtained from dicing the wafer 12 in FIG. 5 has a second smallest width or a width between widths of the die 24 and the die 46, the third level die 46 from bottom to top has a third smallest width or a width between widths of the die 36 and the die 52, and the uppermost level die 52 has the maximum width.

Overall, the present invention discloses a wafer to wafer stacking technique applied in high bandwidth memory (HBM) devices, which first conducts a first dicing process to separate a first wafer into a plurality of first dies, bonds the first dies onto a second wafer, forms a molding layer around the first dies, forms first bumps on the first dies, conducts a second dicing process to separate the second wafer into a plurality of second dies, and then bonds the first dies onto a third wafer. Next, the above steps for stacking dies could be repeated to form desirable amount of stack structures depending on the demand of the product.

According to an embodiment of the present invention, means for bonding between wafers and/or stack structures could be accomplished by but not limited to for example hybrid bonding process, micro bump bonding process, or gold bump process. By first stacking wafers to form stack structures and then conducting chip probing (CP) test and repair procedures through the RDL, bonding pads, and bumps on the stack structure, it would be desirable to reduce cycle time and overall cost than conventional approach of first conducting CP test and then stacking wafers afterwards.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating semiconductor device, comprising:
performing a first dicing process to separate a first wafer into first dies;
bonding the first dies onto the second wafer;
forming a first molding layer around the first dies;
forming first bumps on the first dies;
performing a second dicing process to separate the second wafer for forming second dies; and
bonding the first dies onto a third wafer.

2. The method of claim 1, further comprising:
forming a second molding layer around the first dies and the second dies;
forming second bumps on the third wafer;
performing a third dicing process to separate the third wafer for forming third dies;
bonding the third dies onto a fourth wafer;
forming a third molding layer around first dies, the second dies, and the third dies;
forming solder balls on the second dies; and
performing a fourth dicing process to separate the fourth wafer for forming fourth dies.

3. The method of claim 2, further comprising grinding the third wafer before forming the second bumps.

4. The method of claim 2, further comprising grinding the second dies and the third molding layer before forming the solder balls.

5. The method of claim 1, further comprising grinding the first dies and the first moldering layer before forming the first bumps.

6. The method of claim 1, wherein a width of the first dies is less than a width of the second dies.

7. The method of claim 2, wherein a width of the first dies is less than a width of the third dies.

8. The method of claim 2, wherein a width of the third dies is less than a width of the fourth dies.

9. A semiconductor device, comprising:
a first die bonded to a substrate;
a second die on the first die;
a third die on the second die;
a fourth die on the third die; and
a molding layer around the first die, the second die, and the third die.

10. The semiconductor device of claim 9, further comprising solder balls between the first die and the substrate.

11. The semiconductor device of claim 9, further comprising:
first bumps between the second die and the third die; and
second bumps between the third die and the fourth die.

12. The semiconductor device of claim 9, wherein a width of the second die is less than a width of the first die.

13. The semiconductor device of claim 9, wherein a width of the first die is less than a width of the third die.

14. The semiconductor device of claim 9, wherein a width of the third die is less than a width of the fourth die.
